(19) United States
(12) Patent Application Publication
(10) Pub. No.: US 2026/0047274 A1
(43) Pub. Date: Feb. 12, 2026

(54) MANUFACTURING DEVICE FOR DISPLAY DEVICE AND MANUFACTURING METHOD OF DISPLAY DEVICE USING THE SAME

(71) Applicant: Samsung Display Co., Ltd., Yongin-Si (KR)

(72) Inventors: CHANGHYEON KIM, Yongin-si (KR); HEEYEON PARK, Yongin-si (KR); SEONGIL EOM, Yongin-si (KR); INWON JANG, Yongin-si (KR)

(21) Appl. No.: 19/056,749

(22) Filed: Feb. 19, 2025

(30) Foreign Application Priority Data
Aug. 7, 2024 (KR) 10-2024-0105672

(51) Int. Cl. H10K 59/12

(52) U.S. Cl. CPC H10K 59/1201

(57) ABSTRACT

A manufacturing device for a display device includes a stage on which an object to be processed is disposed, an air blowing device supplying cooling air having a temperature in a range from about 0 degrees to about room temperature, which is about 25 degrees, to the object to be processed, and a pusher applying a pressure on an adhesive. The object to be processed may include an electronic component including a first surface and a second surface opposite to the first surface in a direction, and the adhesive disposed on the second surface of the electronic component.

### CROSS-REFERENCE TO RELATED APPLICATION(S)

This application claims priority to Korean Patent Application No. 10-2024-0105672 filed on Aug. 7, 2024, and all the benefits accruing therefrom under 35 U.S.C. § 119, the content of which in its entirety is herein incorporated by reference.

### BACKGROUND

### 1. Field

The disclosure relates to a display device including an adhesive. More particularly, the disclosure relates to a manufacturing device for a display device which applies pressure to an adhesive and a manufacturing method of a display device using the manufacturing device for the display device.

### 2. Description of the Related Art

As information technology advances, the importance of display devices, which are the medium of connection between users and information, is becoming increasingly prominent. As a result, the use of display devices such as liquid crystal display devices (“LCD”s), organic light emitting display devices (“OLED”s), and plasma display devices (“PDP”s) has been increasing.

In general, a variety of components may be included in the display device. The components are bonded using an adhesive. For example, a display panel and a cover glass, which is located on the display panel to protect, are bonded to each other using a light-transmitting adhesive.

### SUMMARY

Embodiments of the disclosure provide a manufacturing device for a display device having improved display quality.

Embodiments of the disclosure provide a manufacturing method of a display device using the manufacturing device of a display device.

According to an embodiment, a manufacturing device for a display device includes a stage on which an object to be processed is disposed, wherein the object to be processed includes an electronic component including a first surface and a second surface opposite to the first surface in a direction, and an adhesive disposed on the second surface of the electronic component, an air blowing device supplying cooling air having a temperature in a range from about 0 degrees to about room temperature, which is about 25 degrees, to the object to be processed, and a pusher applying a pressure on the adhesive.

In an embodiment, the adhesive may include a pressure-sensitive adhesive.

In an embodiment, the temperature of the cooling air may be a temperature which increases a modulus of the adhesive.

In an embodiment, the temperature of the cooling air may be equal to or more than about 5 degrees, and equal to or less than about 18 degrees.

In an embodiment, the air blowing device may include a vortex tube, and the vortex tube may include an inlet through which compressed air is supplied, a first outlet through which high-temperature air heated by the supply of the compressed air is discharged, and a second outlet through which cooling air cooled down by the supply of the compressed air is discharged toward the object to be processed.

In an embodiment, the compressed air may include clean-dry-air.

In an embodiment, the manufacturing device for the display device may further include a temperature sensor positioned on the stage and detecting a temperature of the stage.

In an embodiment, the electronic component may include a display panel and a circuit board.

In an embodiment, the manufacturing device for the display device may further include a bending arm chucking a portion of the first surface of the electronic component, and positioning a second portion of the second surface above a first portion of the second surface of the electronic component by bending the portion of the first surface.

According to an embodiment, a manufacturing method of a display device includes positioning an object to be processed on a stage, wherein the object to be processed includes an electronic component including a first surface and a second surface opposite to the first surface in a direction, and an adhesive disposed on the second surface of the electronic component, supplying cooling air having a temperature in a range from about 0 degrees to about room temperature to the object to be processed, and applying a pressure on the adhesive.

In an embodiment, the adhesive may include a pressure-sensitive adhesive.

In an embodiment, the temperature of the cooling air may be a temperature which increases a modulus of the adhesive.

In an embodiment, the temperature of the cooling air may be equal to or more than about 5 degrees, and equal to or less than about 18 degrees.

In an embodiment, the cooling air is formed by compressed air supplied from an outside and passing through a vortex tube.

In an embodiment, the compressed air may include clean-dry-air.

In an embodiment, the manufacturing method of the display device may further include detecting a temperature of the stage before applying the pressure on the adhesive.

In an embodiment, the manufacturing method of the display device may further include chucking a portion of the first surface of the electronic component, and positioning a second portion of the second surface above a first portion of the second surface of the electronic component by bending the portion of the first surface of the electronic component.

In an embodiment, the electronic component on which the adhesive is disposed may include a display panel and a circuit board.

In an embodiment, applying the pressure on the adhesive may include applying the pressure on the first portion of the second surface and the second portion of the second surface, where a portion of the circuit board overlaps with the display panel.

In an embodiment, the manufacturing method of the display device may further include applying a pressure on a third portion of the second surface of the display panel spaced apart from the circuit board.

The manufacturing device for the display device according to an embodiment of the disclosure may include a stage on which an object to be processed is disposed, an air blowing device supplying cooling air having a temperature in a range from about 0 degrees to about room temperature (about 25 degrees) to the object to be processed, and a pusher applying a pressure on the adhesive. The manufacturing method of the display device using the same (the manufacturing device for the display device) may include positioning the object to be processed on the stage, supplying cooling air to the object to be processed, and applying a pressure on the adhesive. As the cooling air increases the modulus of the adhesive, an occurrence of a defect due to the pressed down of the adhesive may be prevented.

### BRIEF DESCRIPTION OF THE DRAWINGS

The above and other features of embodiments of the disclosure will become more apparent with reference to the description below and accompanying drawings.

FIG. 1 is a front view illustrating a manufacturing device for a display device according to an embodiment of the disclosure.

FIG. 2 is a top view illustrating the manufacturing device for the display device of FIG. 1.

FIG. 3 is a view illustrating the air blowing device included in the manufacturing device for the display device of FIG. 1.

FIG. 4 is a graph illustrating the temperature of the air blown in the air blowing device of FIG. 3.

FIGS. 5, 6, 7, 8, 9, 10, and 11 are views illustrating a manufacturing method of the display device using the manufacturing device for the display device of FIG. 1.

FIG. 12 is a top view of the display panel of the display device manufactured using the manufacturing device for the display device of FIG. 1.

FIG. 13 is a cross-sectional view of the display panel along X-X′ line of FIG. 12.

### DETAILED DESCRIPTION OF THE EMBODIMENTS

The disclosure may be subjected to various modifications and transformations, and it is intended to describe certain embodiments of the disclosure in detail with reference to drawings. The effects and characteristics of the disclosure and the method of achieving them will be clarified by referring to the embodiments described in detail with the accompanying drawings. However, it should be understood that the disclosure is not limited to the embodiments disclosed below, and may cover various forms or modifications that is within the scope of the skilled person in the art.

When describing embodiments of the disclosure with reference to the drawings, the same or similar elements may be identified using the same reference numerals, and redundant descriptions thereof may be omitted.

In the following description, the terms, such as “first,” “second,” or etc., may be used only to distinguish one element from another and do not intend to be used in a definite sense.

In the following description, singular expressions may include plural expressions, unless the context clearly indicates otherwise.

In the following description, terms, such as “include,” “have,” “comprise” and their modifications, may indicate the presence of the features or elements described in the specification but do not preclude the possibility of additional features or elements being presented.

In the following description, when a part of a layer, area, or element is referred to as being “on” another part of the layer, area or element, it may indicate not only that the part of the layer, area or element directly on another part of the layer, area, or element, but also that the part of the layer, area or element is disposed indirectly on another part of the layer, area or element, i.e., the other layer, area or element may be intervened in the middle thereof.

In drawings, elements may be exaggerated or reduced in size for ease of explanation. For example, the size and thickness of each elements or configuration shown in the drawing are arbitrarily illustrated for ease of description, and the disclosure is not necessarily limited to what is shown.

In the following descriptions, the first, second, and third directions may indicate directions along x-axis, and the y-axis and z-axis but the disclosure is not limited to the three axes on the Cartesian coordinate system. For example, the x, y, and z axes may be orthogonal to each other, but they can also indicate different directions that are not orthogonal to each other.

If an embodiment can be implemented differently, a particular process sequence may be performed in an order different from the described sequence. For example, two processes described consecutively may be performed substantially simultaneously, or in the opposite order of the described sequence.

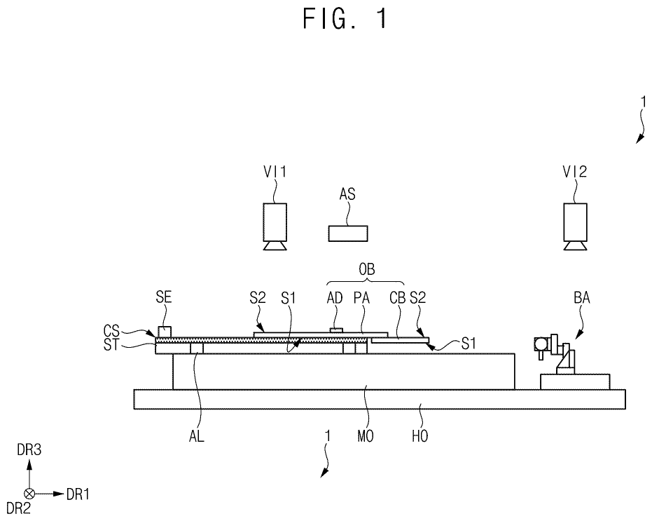

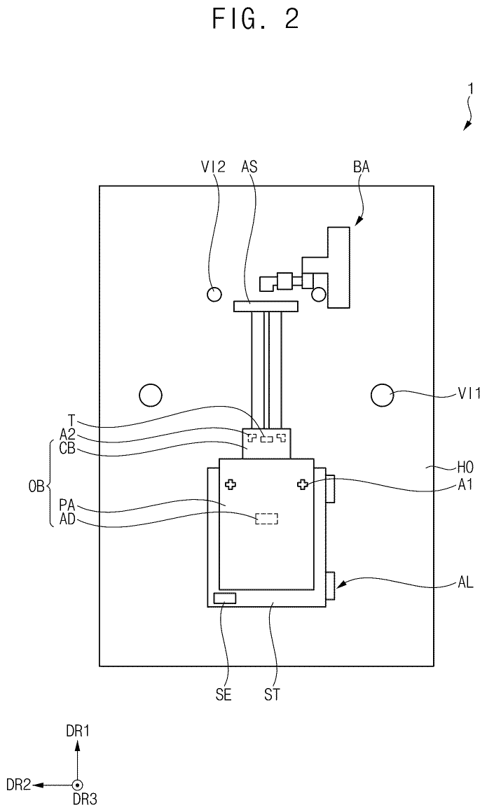

FIG. 1 is a front view illustrating a manufacturing device for a display device according to an embodiment of the disclosure. FIG. 2 is a top view illustrating the manufacturing device for the display device of FIG. 1.

Referring to FIGS. 1 and 2, the manufacturing device for the display device 1 may include a housing HO, a stage ST, a bending arm BA, a driver MO, an aligner AL, a first vision VI1, a second vision VI2, and an air blowing device AS.

The housing HO may include multiple frames, plates, or the like. For example, the housing HO may have a chamber form. However, the disclosure is not limited thereto.

An object to be processed OB may include an electronic component and an adhesive AD. The electronic component may include a display panel PA and a circuit board CB which is connected to the display panel PA.

The electronic component may include a first surface S1 and a second surface S2. For example, the first surface S1 is opposite to the second surface S2 in a thickness direction (for example, the third direction DR3). For example, the first surface S1 may be adjacent to the stage ST, and the second surface S2 may be spaced farther from the stage ST than the first surface S1.

For example, the adhesive AD may be disposed in various ways depending on a size of the electronic component. For example, the adhesive AD may be located only on a portion of the display panel PA. The adhesive AD may be located on the second surface S2 of the display panel PA.

The adhesive AD according to an embodiment may include a pressure-sensitive adhesive. For example, the pressure-sensitive adhesive may include an optical clear adhesive. The pressure-sensitive adhesive may be a material which, when pressure is applied to an adhesive surface, acts as an adhesive material. The optical adhesive may be a kind of the pressure-sensitive adhesive. A structure with the optical adhesive may improve visibility by minimizing changes caused by the reflection and refraction of light at layers of different materials, compared to an air gap structure (i.e., a structure filled with air).

For example, the optical adhesive may include both a UV adhesive and a normal adhesive. For example, the UV adhesive may be an adhesive whose modulus increases through UV curing, and the normal adhesive may be an adhesive having a high modulus without requiring the UV curing.

The object to be processed OB in the manufacturing device for the display device 1 is not limited to the display panel PA, the circuit board CB and the adhesive AD bonding the display panel PA and the circuit board CB, as described above. For example, the manufacturing device for the display device 1 may be applied to a variety of objects to be processed OB. For example, the object to be processed OB may include the display panel PA, a cushion layer that protects a back surface of the display panel PA, and the adhesive AD that bonds the display panel PA to the cushion layer. For example, the object to be processed OB may include the display panel PA, a fingerprint sensor located on the display panel PA, and an adhesive AD that bonds the display panel PA to a fingerprint sensor. For example, the object to be processed OB may include the display panel PA, a mold that surrounds an outer edge of the display panel PA, and the adhesive AD that bonds the display panel PA to the mold.

A portion of the first surface S1 of the electronic component may be in contact with the stage ST, and a remainder of the first surface S1 might not be in contact with the stage ST. For example, the first surface S1 of the display panel PA may be seated on the stage ST, and the first surface S1 of the circuit board CB may be spaced away from the stage ST.

The electronic component may have flexible properties. For example, a substrate of the display panel PA may include plastic, and the circuit board CB may also include the plastic. In this case, the display panel PA and circuit board CB may be bent in whole or in part.

A display area may be defined either in the second surface S2 or in the first surface S1 of the display panel PA. For example, the display area may be defined in the second surface S2, and the first surface S1 may be the back surface on which the display area is not formed.

According to an embodiment, the object to be processed OB may be disposed on the stage ST. For example, the stage ST may include a first chuck CS. The first chuck CS may be a device which fixes the electronic component to the stage ST. For example, the first chuck CS may include an electrostatic chuck, an adhesive chuck, a clamp, a jig, a flow path connected to a pump, or the like.

According to an embodiment, the bending arm BA may be located on the housing HO.

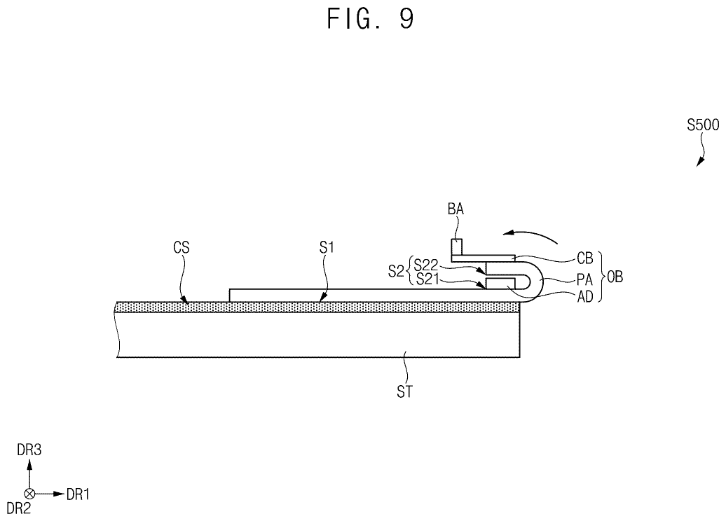

According to an embodiment, the bending arm BA may attach to a portion of the electronic component and place the portion of the electronic component above another portion of the electronic component by bending the portion of the electronic component. For example, the bending arm BA may chuck, e.g., attach to, a portion of the first surface S1 of the electronic component, and position a second portion of the second surface S2 (for example, a second portion S22 of the second surface S2) above a first portion of the second surface S2 (for example, a first portion S21 of the second surface S2 of FIG. 9) by bending the portion of the first surface S1. For example, before the bending, the first portion S21 of the second surface S2 is in level with the second portion S22 of the second surface S2 (e.g., both are disposed to form a straight surface in the first direction DR1. However, the second portion S22 of the second surface S2 may be positioned on the first portion S21 of the second surface S2 in the third direction DR3 (see the first portion S21 and the second portion S22 in FIG. 9).

The bending arm BA may include various components, such as a support, a linear driver, and a rotator.

The support of the bending arm BA may extend in the third direction DR3. For example, the third direction DR3 may be a direction that crosses a surface of the housing HO.

A surface of the housing HO may be defined by the first direction DRI and the second direction DR2. The first direction DR1, the second direction DR2, and the third direction DR3 may cross with each other. For example, the first direction DR1, the second direction DR2, and the third direction DR3 may be perpendicular to each other. The third direction DR3 may be a direction perpendicular to the surface of the housing HO.

The linear driver of the bending arm BA may be connected to the support and may make a linear motion in one direction (for example, in the first direction DR1, in the second direction DR2, or in the third direction DR3). For example, the linear driver may include a ball screw and a motor connected with the ball screw. However, the disclosure is not limited thereto. For example, the linear driver may include a pulley and a belt, a linear motor, or the like.

The rotator of the bending arm BA may include a second chuck for chucking, e.g., attaching to, the first surface S1 of the electronic component and a rotator for rotating the electronic component.

For example, the second chuck may include an electrostatic chuck, an adhesive chuck, a clamp, a jig, a flow path connected with a pump, or the like. For example, the second chuck may chuck, e.g., attach to, the object to be processed OB while avoiding a terminal, a pad, a line, or the like formed on the object to be processed OB. For example, the second chuck may chuck, e.g., attach to, a chucking part T.

For example, the rotator may include a rotary motor and a gear unit connected with the rotary motor, a rotary cylinder, a rotary pulley connected with the rotary motor, a rotary belt connected with the rotary pulley, or the like. However, the disclosure is not limited thereto. For example, the rotator may move along a pre-set bending path.

According to an embodiment, a portion of the display panel PA (i.e., a first bending part) may be bent. For example, the first bending part of the display panel PA may not include the terminal, the pad, the line, or the like. In addition, a pixel might not be located in the first bending part. However, the disclosure is not limited thereto. For example, a portion of the circuit board CB (i.e., a second bending part) may be bent, and the second bending part of the circuit board CB may not include the terminal, the pad, the line, or the like.

According to an embodiment, the second chuck may chuck, e.g., attach to, the first surface S1 of the circuit board CB. After the first surface S1 of the circuit board CB is chucked, the first surface S1 of the circuit board CB may be bent. Accordingly, a position of the first surface S1 of the circuit board CB may be changed. A portion of the second surface S2 of the display panel PA may be bent to face a remaining part of the second surface S2 in the third direction (for example, refer to FIG. 9). However, the disclosure is not limited thereto. For example, the second chuck may chuck, e.g., attach to, the first surface S1 of the display panel PA to bend the display panel PA and place a portion of the second surface S2 of the display panel PA above a remaining portion the second surface S2 of the display panel PA in the third direction.

However, this is an example, and the structure of the bending arm BA may be modified in various ways.

The driver MO may be located between the housing HO and the stage ST. For example, the driver MO may move the stage ST back and forth in one direction (for example, in the third direction DR3). For example, the driver MO may include a ball screw and a motor connected to the ball screw, a linear motor, a variable cylinder, or the like.

The aligner AL may be located on the stage ST. For example, the aligner AL may adjust the position of the stage ST. For example, the aligner AL may move the stage ST in the first direction DR1 and/or in the second direction DR2. Through the aligner AL, the stage ST may be linearly moved in the first direction DR1 and/or the second direction DR2, or be rotated. For example, the aligner AL may include the motors, the cylinder, or the like.

The first vision VI1 may be located on a travel path of the stage ST. For example, the first vision VI1 may be located between an initial position of the stage ST and the bending arm BA. The first vision VI1 may detect a first position of the object to be processed OB on the stage ST. For example, the first vision VI1 may include a CCD, a camera, or the like.

The second vision VI2 may be spaced apart from the bending arm BA in the third direction DR3. The second vision VI2 may detect a position of the object to be processed OB located below the bending arm BA. For example, the second vision VI2 may include CCDs, cameras, or the like. The first vision VII and the second vision VI2 may be a same device, or may be different devices.

The first vision VI1 may detect the first position of the object to be processed OB on the stage ST through a first alignment mark A1 formed on the display panel PA. For example, the first alignment mark A1 may be formed on the second surface S2 of the display panel PA.

After alignment based on the first alignment mark A1, the object to be processed OB may be moved towards the bending arm BA. At this time, the driver MO may move the stage ST to position the object to be processed OB adjacent to the bending arm BA. However, the disclosure is not limited thereto. For example, the stage ST may remain stationary, while the bending arm BA moves.

The second vision VI2 may detect the position of the object to be processed OB located below the bending arm BA through a second alignment mark A2 formed on the display panel PA. For example, the second alignment mark A2 may be formed on the first surface S1 of the circuit board CB.

The position accuracy of a bending adhesion process may be determined using the second alignment mark A2. For example, if the second alignment mark A2 is located within a predetermined range compared to a reference align mark, it may be determined that the bending adhesion process has been performed at a correct location. However, if the second alignment mark A2 is located outside the predetermined range compared to the reference align mark, it may be determined that the bending adhesion process was performed at an incorrect position (i.e., resulting in adhesion failure). In a case of the adhesion failure, the breakage, damage, or the like of the electronic component due to a stress concentration after the bending may occur.

According to an embodiment, the air blowing device AS may be located on a housing HO. For example, the air blowing device AS may be located on the object to be processed OB. The air blowing device AS may blow cooling air having a temperature less than about room temperature toward the object to be processed OB.

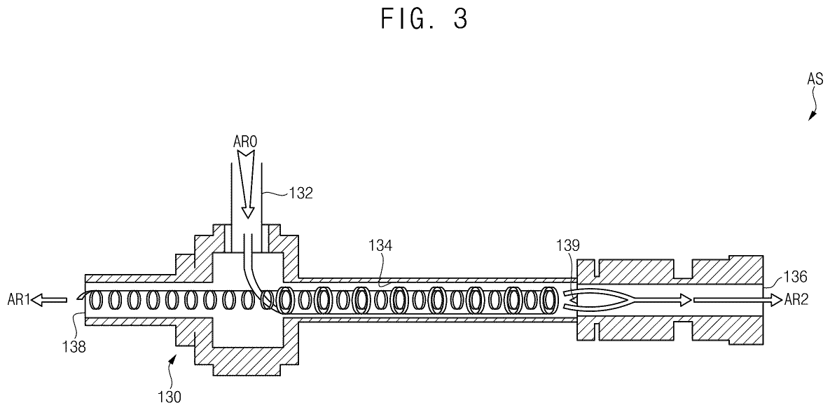

Detailed descriptions of the air blowing device AS is described below with reference to FIG. 3.

According to an embodiment, a temperature sensor SE may be located on the stage ST. For example, the temperature of the object to be processed OB may be indirectly checked from the temperature sensor SE located on the stage ST.

For example, if the temperature sensor SE is placed on the object to be processed, additional time, cost, and effort may be required to position the object to be processed OB and install the temperature sensor SE.

However, when the temperature sensor SE is located on the stage ST, the additional time, cost, and effort may be reduced. Since heat conduction occurs rapidly in the object to be processed OB and heat quickly transfers from the object to be processed OB to the stage ST, the temperature sensor SE may be located on the stage ST to monitor the temperature of the object to be processed OB indirectly.

However, the FIGS. 1 and 2 are illustrative, and the disclosure is not limited to thereto. For example, the manufacturing device for the display device 1 may include more component(s), or all or some of the components described above may be omitted or substituted.

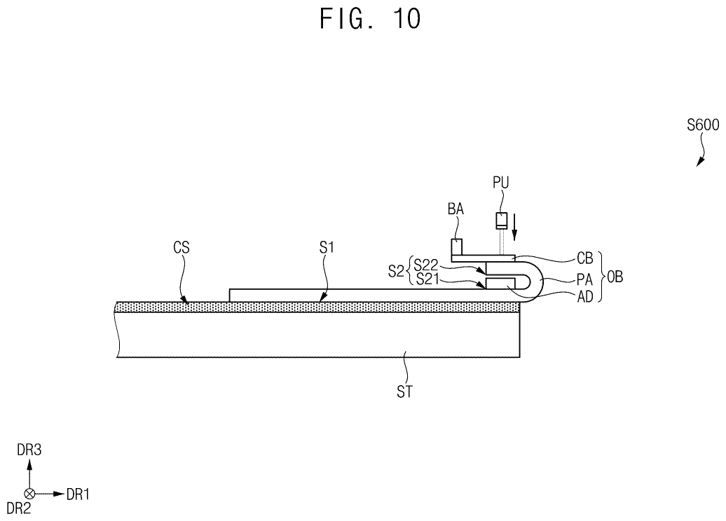

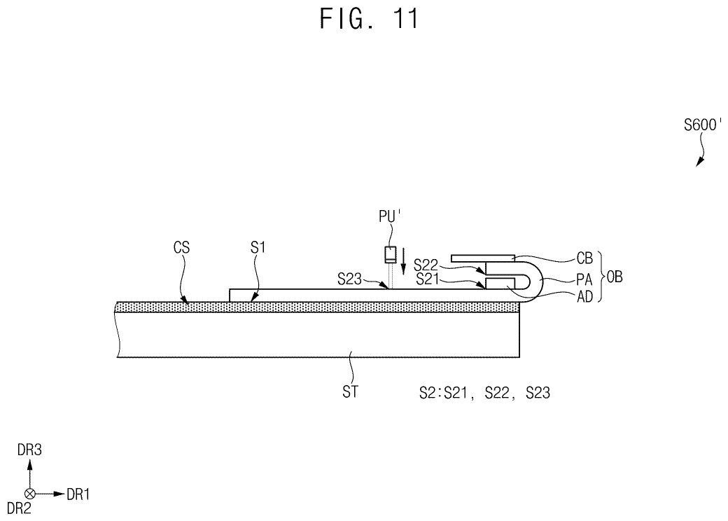

According to an embodiment, the manufacturing device for the display device 1 may include a pusher (for example, a pusher PU shown in FIG. 10 or a pusher PU′ shown in FIG. 11). For example, the pusher may be connected to the bending arm BA or may be provided as a separate device from the bending arm BA. For example, the pusher may include a ball screw and a motor connected to the ball screw, a pressurized cylinder. However, the disclosure is not limited thereto.

According to an embodiment, the pusher may apply a pressure on the object to be processed OB. Accordingly, the portion of the second surface S2 of the display panel PA may be bonded to the adhesive AD.

FIG. 3 is a view illustrating the air blowing device included in the manufacturing device for the display device of FIG. 1.

The air blowing device may perform a function of cooling the adhesive AD disposed on the object to be processed OB, as depicted in FIG. 1, to increase the modulus of the adhesive AD.

Referring to FIG. 3, the air blowing device AS according to an embodiment may include a vortex tube 130. The vortex tube 130 may be located on the stage ST and may be configured to blow air (for example, cooling air) toward the object to be processed OB on the stage ST.

The vortex tube 130 may include an inlet 132, a first outlet 136, and a second outlet 138.

Compressed air ARO may be supplied into the inlet 132. The compressed air 142 may be supplied into a tubular vortex rotating chamber 134. For example, the compressed air ARO may include clean-dry-air (“CDA”).

In the vortex rotation chamber 134, air initially rotating at millions of RPM (i.e., a primary vortex) is partially discharged through the first outlet 136, and the remaining air is recirculated through a regulating valve 139, through which a secondary vortex may be formed inside the primary vortex. The secondary vortex may be discharged through the second outlet 138. In other words, within an inner space of the vortex tube 130, distinct vortices that proceed in opposite directions may be formed along a longitudinal direction, e.g., the primary vortex disposing outside of the inner space of the vortex tube 130 is proceeding to the first outlet 136, while the secondary vortex disposing relatively inside of the inner space of the vortex tube 130, compared to the primary vortex, is proceeding to the second outlet. Through the first outlet 136, high-temperature air AR2, heated by supply of the compressed air ARO, may be discharged, and through the second outlet 138, a cooling air AR1, which is cooled down by supply of the compressed air AR0, may be discharged toward the object to be processed OB.

The secondary vortex may lose heat as it passes through a lower pressure region inside the primary vortex and may be directed to the second outlet 138. For example, the primary vortex and the secondary vortex may rotate in a same direction, e.g., in the same clockwise or in the same counterclockwise direction, and at a same angular velocity. Since one rotation time of the air particles in the secondary vortex and the air particles in the primary vortex are the same (equal angular velocity), a motion speed of the air particles of the secondary vortex may be less than a motion speed of the air particles of the primary vortex. A decrease in the motion velocity may mean a decrease in kinetic energy, and the reduced kinetic energy may be converted into heat which further increases the temperature of the air particles (i.e., the hot air AR2) of the primary vortex, and further lowers the temperature of the air particles (i.e., the cooling air AR1) of the secondary vortex.

However, FIG. 3 is illustrative, and the disclosure is not limited thereto. For example, any device capable of providing a cooling air, even if it uses a different way than the vortex tube describe above, may be used as the air blowing device AS without restriction. For example, the compressed air may be cooled in a chiller, passed through a dryer to remove moisture and a foreign material, and may be blown to the object to be processed OB.

In addition, although not shown, the air blowing device AS may include a variety of additional components. For example, the air blowing device AS may further include a blowing-angle adjuster that adjusts the blowing-angle of the cooling air AR1, an angle limiter that adjusts the blowing-range of the cooling air AR1, and a linear shifter that adjusts a distance between the stage ST and the air blowing device AS.

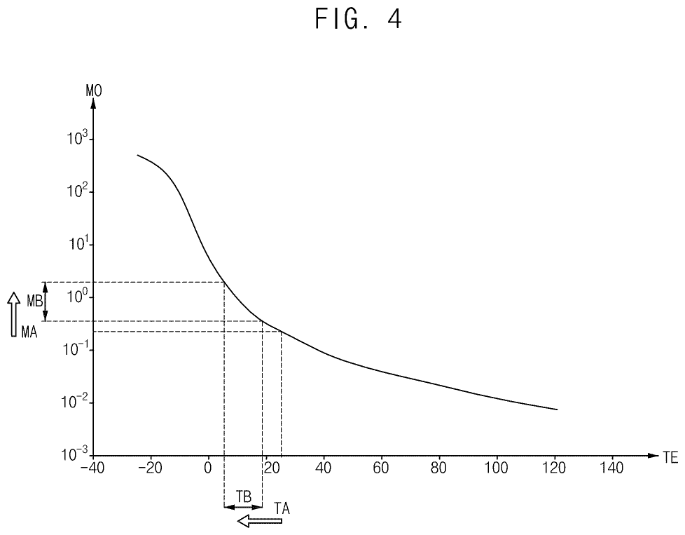

FIG. 4 is a graph illustrating the temperature of the air blown in the air blowing device of FIG. 3.

For example, FIG. 4 is an organized view of temperature-dependent storage modulus of UV adhesive (hereinafter, referred to as “OCA”). X-axis represents the temperature (unit: Celsius degrees) and Y-axis represents the storage modulus (unit: megapascals).

Referring to FIGS. 3 and 4, the air blowing device (for example, the air blowing device AS of FIG. 1) according to an embodiment may blow the cooling air to the object to be processed OB.

According to an embodiment, the cooling air may have a temperature (for example, temperature in a second temperature range TB shown in FIG. 4) that increases the modulus value (for example, a value in a second modulus range MB shown in FIG. 4) of the adhesive AD (i.e., the pressure-sensitive adhesive, the optical adhesive).

For example, the temperature of the cooling air (the temperature in the second temperature range TB) may be equal to or more than about 5 degrees and equal to or less than about 18 degrees.

For example, if the temperature of the cooling air is less than about 5 degrees, dew may form on the first chuck CS of the stage ST. In this case, a chucking force of the first chuck CS, which represents a power to hold the electronic component, may be reduced, thereby reducing the accuracy of the bending adhesion process.

On the other hand, if the temperature of the cooling air exceeds about 18 degrees, the modulus of the adhesive AD may decrease, causing the adhesive AD to flow more easily. Accordingly, a waviness of the adhesive AD may increase, and a user may notice wave-like defect.

In the room temperature (about 25 degrees, TA of FIG. 4), the storage modulus of the OCA was about 0.23 megapascals. At about 10 degrees, the storage modulus of the OCA was increased to about 1.1 megapascals. As a result of decreasing the temperature by about 15 degrees, the storage modulus was increased by about 4.8 times.

As a result of the bending after supplying the cooling air having a reduced temperature, the user hardly perceives the wave-like defect caused by the waviness of the OCA. In addition, as a result of the bending after supplying the cooling air within the temperature range above, neither bubbles nor step differences in an area with curvature formed. In other words, the bubbles and the step defect due to the increase in the modulus did not occur.

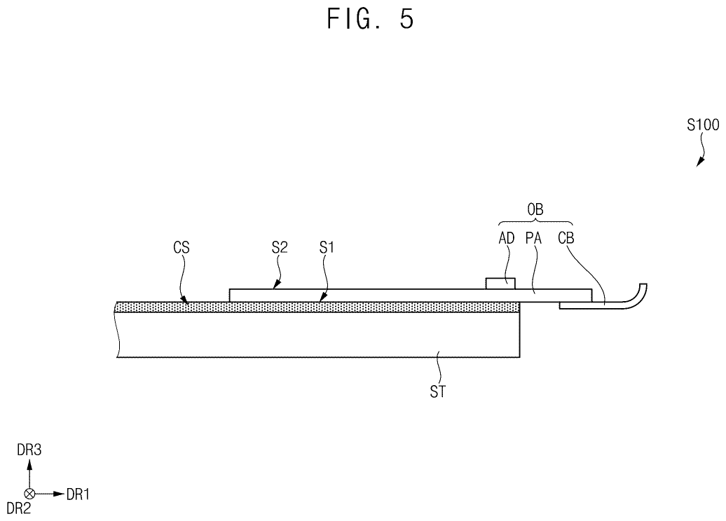

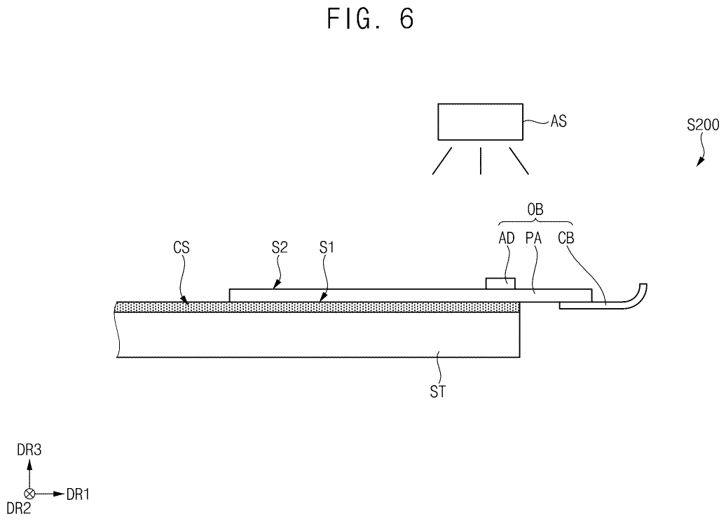

FIGS. 5, 6, 7, 8, 9, 10, and 11 are views illustrating a manufacturing method of the display device using the manufacturing device for the display device of FIG. 1.

Hereinafter, any repetitive detailed descriptions of the manufacturing device for the display device described above with reference to FIGS. 1, 2, 3, and 4 will be omitted or simplified.

Referring to FIG. 5, the object to be processed OB may be positioned on stage ST (S100).

According to an embodiment, the object to be processed OB may include the electronic component and the adhesive AD which is disposed on the electronic component.

According to an embodiment, the adhesive AD may include the pressure-sensitive adhesive.

The electronic component may include the first surface S1 and the second surface S2. The first surface S1 and the second surface S2 may be opposite to each other in a direction (for example, the third direction DR3). According to an embodiment, the electronic component may include the display panel PA and the circuit board CB. The adhesive AD may be positioned on the second surface S2 of the display panel PA.

The object to be processed OB may be chucked by the first chuck CS included in the stage ST. For example, the first chuck CS of the stage ST may chuck, e.g., attach to, the first surface S1 of the electronic component.

Referring to FIGS. 3, 4 and 6, according to an embodiment, the cooling air AR1 having the temperature below the room temperature may be supplied toward the object to be processed OB (S200).

According to an embodiment, the cooling air AR1 may be formed as the compressed air AR0 provided from the outside passes through the vortex tube 130 included in the air blowing device AS.

According to an embodiment, the compressed air AR0 may include the clean-dry-air (“CDA”).

According to an embodiment, the cooling air AR1 may have the temperature that increases the modulus of the adhesive AD. For example, the temperature of the cooling air AR1 (for example, the temperature in the second temperature range TB of FIG. 4) may be equal to or more than about 5 degrees and equal to or less than about 18 degrees.

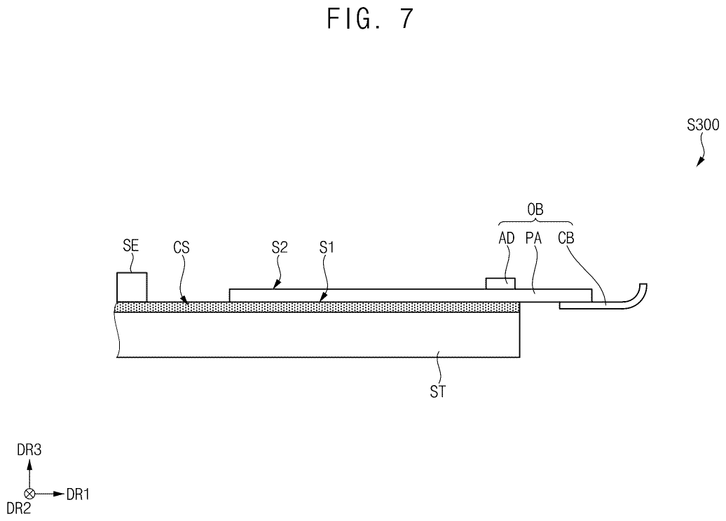

Referring to FIG. 7, according to an embodiment, the temperature of the stage ST may be detected (S300). For example, the temperature sensor SE positioned on the state ST may indirectly detect, through the temperature of the stage ST, the temperature of the adhesive AD included in the object to be processed OB. Through this, the modulus of the adhesive AD may be inferred from a pre-set table (for example, refer to FIG. 4).

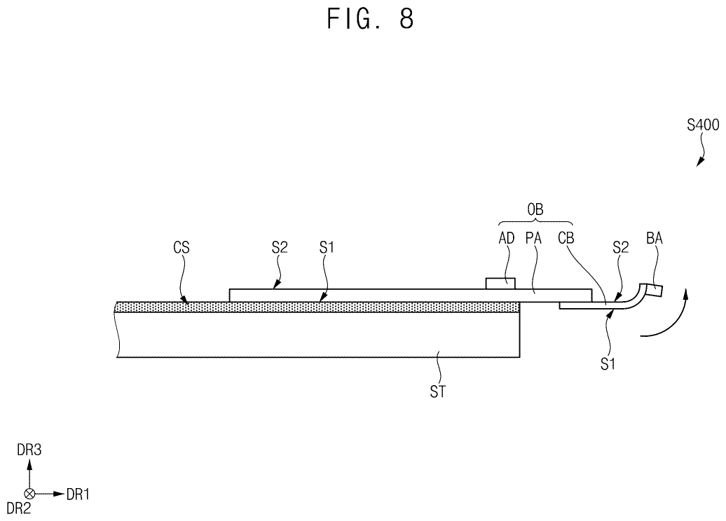

Referring to FIGS. 8 and 9, according to an embodiment, a portion of the first surface S1 of the electronic component may be chucked after the supply of the cooling air to the object to be processed OB (S400), and the portion of the first surface S1 of the electronic component may be bent, making the second portion S22 of the second surface positioned above the first portion S21 of the second surface of the electronic component, e.g., making the first portion S21 and the second portion S22 of the second surface S2 of the electronic component face each other (S500).

At this time, as the modulus of the adhesive AD increases due to the cooling air, as described above, the occurrence of the defect due to the waviness of the adhesive AD may be further decreased.

Referring to FIGS. 10 and 11, the adhesive AD may be applied with a pressure.

As shown in FIG. 10, the pusher PU may apply the pressure on the first portion S21 of the second surface S2 and the second portion S22 of the second surface, where a portion of the circuit board CB overlaps with a portion of the display panel PA. By applying the pressure, e.g., pressurizing, with the pusher PU, the first portion S21 and the second portion S22 of the second surface S2 may be bonded together through the adhesive AD.

According to an embodiment, as shown in FIG. 11, a third portion S23 of the second surface S2 of the display panel PA spaced apart from the circuit board CB may be applied with a pressure. The third portion S23 may be spaced apart in a direction (for example, in the opposite direction of the first direction DR1) from the first portion S21 and the second portion S22 of the second surface S2. For example, the third portion S23 may be a portion where an integrated chip is located. The part where the integrated chip is located may have a high step difference. The step difference may cause the defect due to the waviness. The disclosure according to an embodiment may reduce the occurrence of the defect due to the waviness by supplying the cooling air and pressurizing with the pusher PU′.

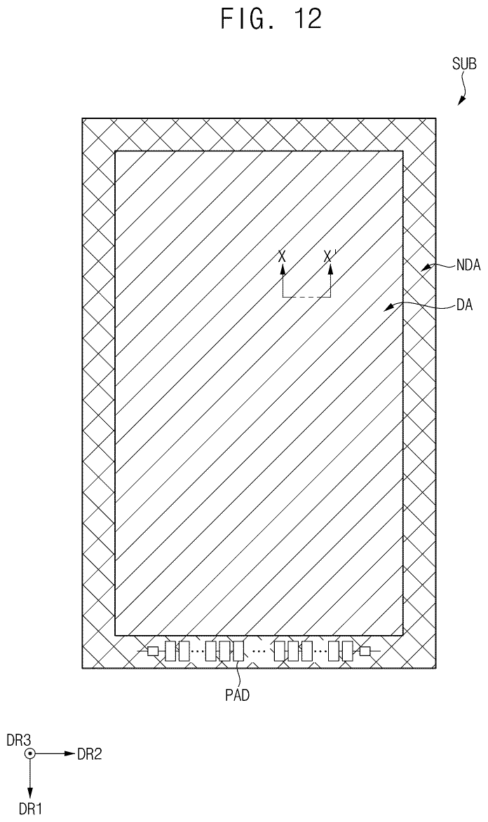

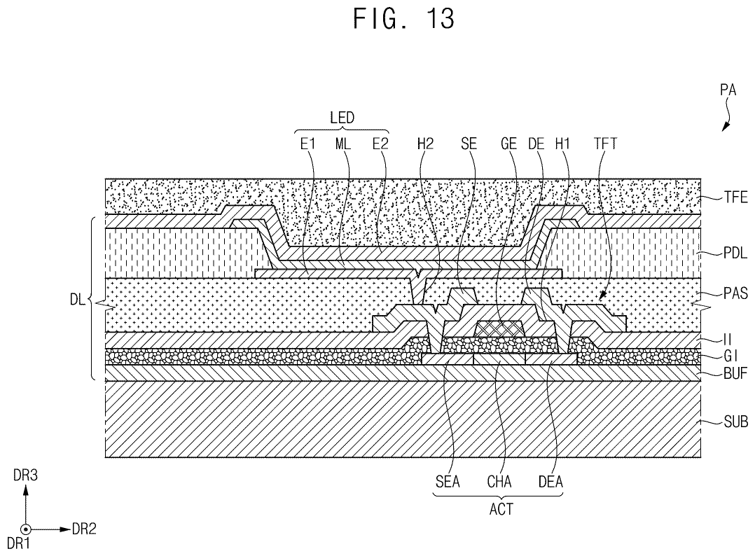

FIG. 12 is a top view of the display panel of the display device manufactured using the manufacturing device for the display device of FIG. 1. FIG. 13 is a cross-sectional view along X-X′ line of FIG. 12.

Referring to FIGS. 12 and 13, the display panel PA may include a plurality of layers on a base substrate SUB. The PAD may be a part where the display panel PA and the circuit board of FIG. 1 are connected. For example, the display panel PA may include the base substrate SUB, a buffer layer BUF, a displaying layer DL, and an encapsulation layer TFE in the display area DA of the display panel PA.

The displaying layer DL may include a transistor TFT, a gate insulating layer GI, an interlayer insulating layer II, a passivation layer PAS, a light-emitting element LED, and a pixel defining layer PDL.

A display area DA may include a light-emitting region and a non-light-emitting region. For example, the transistor TFT and the light-emitting elements LED may be located in the light-emitting region.

For example, the transistor TFT may include an active layer ACT, a gate electrode GE, a source electrode SE, and a drain electrode DE. The light-emitting element LED may include a first electrode E1, an intermediate layer ML, and a second electrode E2.

The non-light-emitting region may surround the light-emitting region in a plan view. Here, the plan view may mean a view along the third direction DR3.

The base substrate SUB may include glass, quartz, plastic, SUS, titanium (“Ti”), or the like. For example, the base substrate SUB may have flexible, bendable, or rollable properties.

The buffer layer BUF may be disposed on the base substrate SUB. The buffer layer BUF may include an inorganic insulating material. For example, the buffer layer BUF may include silicon oxide, silicon nitride, silicon oxide, or the like. The buffer layer BUF may prevent an impurity from being diffused into or damaging the active layer ACT of the transistor TFT. However, the disclosure is not limited thereto. For example, the buffer layer BUF may include an organic insulating material.

The active layer ACT may be disposed on the buffer layer BUF. According to an embodiment, the active layer ACT may include a silicon semiconductor material. For example, the active layer ACT may include amorphous silicon, polycrystalline silicon, or the like. According to an embodiment, the active layer ACT may include oxide semiconductor material. For example, the active layer ACT may include zinc oxide, zinc-tin oxide, zinc-indium-oxide, indium-oxide, titanium-oxide, indium-gallium-zinc-oxide, indium-zinc-tin-oxide, or the like. According to an embodiment, the active layer ACT may include an organic semiconductor material.

The active layer ACT may include a source region SEA, a drain region DEA, and a channel region CHA that is interposed between the source region SEA and the drain region DEA.

For example, the active layer ACT may be formed by forming an amorphous silicon layer on the buffer layer BUF, crystallizing the amorphous silicon layer, and patterning the crystallized silicon layer. For example, the active layer ACT may be doped with impurities in the source region SEA and drain region DEA, depending on a type of TFT (for example, driving TFT, switching TFT, or the like).

The gate insulating layer GI may be disposed on the active layer ACT. The gate insulating layer GI may include an inorganic insulating material. For example, the gate insulating layer GI may include silicon oxide, silicon nitride, silicon oxide, titanium-oxide, tantalum oxide, or the like. The gate insulating layer GI may electrically insulate the active layer ACT from the gate electrode GE from each other.

The gate electrode GE may be disposed on the gate insulating layer GI. The gate electrode GE may include a conductive material. For example, The gate electrodes GE may include a metal, an alloy, a conductive metal oxide, a transparent conductive material, or the like. The gate electrodes GE may be applied with a gate signal. The gate signal may turn on/off the transistor TFT to adjust an electrical conductivity of the active layer ACT.

The interlayer insulating layer II may be disposed on the gate electrode GE. The interlayer insulating layer II may include an organic and/or an inorganic insulating material. The interlayer insulating layer II may electrically insulate the source electrode SE and the drain electrode DE from the gate electrode GE.

The source electrode SE and drain electrode DE may be disposed on the interlayer insulating layer II. The source electrode SE and the drain electrode DE may include a conductive material. For example, the source electrode SE and the drain electrode DE may include a metal, an alloy, a conductive metal oxide, a transparent conductive material, or the like.

The source electrode SE and drain electrode DE may be in electrical contact with the active layer ACT through a contact hole H1 that passes through the interlayer insulating layer II and the gate insulating layer GI. For example, the source electrode SE may be connected to the source region SEA and the drain electrode DE may be connected to the drain region DA through a contact hole H1 in the interlayer insulating layer II and gate electrode GE.

The passivation layer PAS may be disposed on the source electrode SE and the drain electrode DE. The passivation layer PAS may include an organic insulating material. For example, the passivation layer PAS may include a polyacrylic resin, a polyimide-based resin, an acrylic-based resin, or the like. A top surface of the passivation layer PAS may be substantially flat. For example, the passivation layer PAS may be formed with a transparent insulator to achieve a resonant effect. For example, the passivation layer PAS may include two or more layers including organic and/or inorganic matter. However, the disclosure is not limited thereto.

For another example, the top surface of the passivation layer PAS may be formed to bend according to a curvature of an underlying layer. In this case, the passivation layer PAS may also include an inorganic insulating material.

The first electrode E1 may be disposed on the passivation layer PAS. The first electrode E1 may include a conductive material. For example, the first electrode E1 may include a metal, an alloy, a conductive metal oxide, a transparent conductive material, or the like.

The first electrode El may be electrically connected to the source electrode SE or the drain electrode DE through a contact hole H2 that passes through the passivation layer PAS. According to an embodiment, the first electrode E1 may be referred to as an anode electrode.

The pixel defining layer PDL may be disposed on the passivation layer PAS and cover a portion of the first electrode E1. The pixel defining layer PDL may include an organic insulating material. For example, the pixel defining layer PDL may include a polyacrylic compound, a polyimide-based compound, or the like. The pixel defining layer PDL may including a pixel opening to partition the light-emitting region of the pixel. The pixel opening defined in the pixel defining layer PDL may extend to the first electrode E1.

The intermediate layer ML may be disposed on the first electrode El in the pixel opening. The intermediate layer ML may include an organic light-emitting material. According to an embodiment, the intermediate layer ML may have a multi-layered structure including various functional layers. For example, the intermediate layer ML may include at least one of a hole injection layer, a hole transport layer, an electron transport layer, or an electron injection layer.

The second electrode CE may be disposed on the intermediate layer ML and cover the pixel defining layer PDL. According to an embodiment, the second electrode CE may be referred to as a cathode electrode.

In addition, the intermediate layer ML and the second electrode E2 may be formed on the first electrode E1.

The first electrode E1 and the second electrode E2 may be separated from each other by the intermediate layer ML, and light may be emitted from the organic light-emitting layer by applying voltages of different polarities to the intermediate layer ML. On the other hand, a unit pixel may include a plurality of sub pixels, and the plurality of sub pixels may emit light of various colors. For example, each of the plurality of sub pixels may emit any one of red, green, or blue lights. However, the disclosure is not limited thereto. For example, the plurality of sub pixels may emit white light.

The encapsulation layer TFE may have a multi-layered structure. For example, the encapsulation layer TFE may include at least one organic layer interposed between at least two inorganic layers. For example, the encapsulation layer TFE may include at least one inorganic layer interposed between at least two organic layers. For example, the encapsulation layer TFE may include at least an organic layer interposed between at least two inorganic layers, and at least an inorganic layer interposed between at least two organic layers.

According to an embodiment, the encapsulation layer TFE may include an organic layer. For example, the organic layer may include a polymer. For example, the polymer may include polyethylene terephthalate, polyimide, polycarbonate, epoxy, polyethylene, polyacrylate, or the like. Each of them may be used alone or in combination with each other. However, the disclosure is not limited thereto. The organic layer may include a material polymerized monomer composition. For example, The monomer composition may include a mono-acrylate-based monomer, a de-acrylate-based monomer, a tri-acrylate-based monomer, a photo-initiator such as TPO (2,4,6-tri-methylbenzoyl-diphenyl phosphine oxide), or the like. Each of them may be used alone or in combination with each other. However, the disclosure is not limited thereto.

According to an embodiment, the encapsulation layer TFE may include an inorganic layer. For example, the inorganic layer may include a metal oxide or a metal nitride. For example, the inorganic layer may include SiNₓ, Al₂O₃, SiO₂, TiO₂, or the like. Each of them may be used alone or in combination with each other. However, the disclosure is not limited thereto.

For example, the encapsulation layer TFE may include a first inorganic layer, a first organic layer, and a second inorganic layer sequentially stacked from a top of the light-emitting element LED. For example, the encapsulation layer TFE may include the first inorganic layer, the first organic layer, the second inorganic layer, a second organic layer, and a third inorganic layer sequentially stacked from the top of the light-emitting element LED. For example, the encapsulation layer TFE may include the first inorganic layer, the first organic layer, the second inorganic layer, the second organic layer, the third inorganic layer, a third organic layer, and the fourth inorganic layer sequentially stacked from the top of the light-emitting element LED.

A top layer of the encapsulation layer TFE that is the outermost layer of the display panel PA may be formed with the inorganic layer to prevent the moisture permeation into the light-emitting element LED. However, the disclosure is not limited thereto.

A halide-metal layer may be further included between the light-emitting element LED and the first inorganic layer. For example, the halide-metal layer may include lithium fluoride (“LiF”). In case that the forming of the first inorganic layer by sputtering method, the halide-metal layer may prevent the light-emitting element LED from being damaged. However, the disclosure is not limited thereto.

The manufacturing device for the display device according to an embodiment of the disclosure may be applied to a manufacturing process of the display device used in a computer, a laptop, a mobile phone, a smartphone, a smart pad, a PMP, a PDA, a MP3 player, or the like.

Although the above has been explained with reference to embodiments of the disclosure, it will be understood that a person with ordinary knowledge in the field of technology may modify and change the disclosure in various ways without materially departing from the novel teaching and advantages of the disclosure. Accordingly, it will be understood that all such modifications are intended to be included within the scope of the disclosure as defined in the following claims.

What is claimed is:

1. A manufacturing device for a display device comprising:
a stage on which an object to be processed is disposed, the object to be processed including an electronic component including a first surface and a second surface opposite to the first surface in a direction, and an adhesive disposed on the second surface of the electronic component;
an air blowing device supplying cooling air having a temperature in a range from about 0 degrees to about room temperature, which is about 25 degrees, to the object to be processed; and
a pusher applying a pressure on the adhesive.

2. The manufacturing device for the display device of claim 1, wherein the adhesive includes a pressure-sensitive adhesive.

3. The manufacturing device for the display device of claim 2, wherein the temperature of the cooling air is a temperature which increases a modulus of the adhesive.

4. The manufacturing device for the display device of claim 3, wherein the temperature of the cooling air is equal to or more than about 5 degrees, and equal to or less than about 18 degrees.

5. The manufacturing device for the display device of claim 1, wherein the air blowing device includes a vortex tube, and
wherein the vortex tube includes:
an inlet through which compressed air is supplied;
a first outlet through which high-temperature air heated by the supply of the compressed air is discharged; and
a second outlet through which cooling air cooled down by the supply of the compressed air is discharged toward the object to be processed.

6. The manufacturing device for the display device of claim 1, wherein the compressed air includes clean-dry-air.

7. The manufacturing device for the display device of claim 1, further comprising:
a temperature sensor positioned on the stage and detecting a temperature of the stage.

8. The manufacturing device for the display device of claim 1, wherein the electronic component includes a display panel and a circuit board.

9. The manufacturing device for the display device of claim 1, further comprising:
a bending arm chucking a portion of the first surface of the electronic component, and positioning a second portion of the second surface above a first portion of the second surface of the electronic component by bending the portion of the first surface.

10. A manufacturing method for a display device comprising:
positioning an object to be processed on a stage, the object to be processed including an electronic component including a first surface and a second surface opposite to the first surface in a direction, and an adhesive disposed on the second surface of the electronic component;
supplying cooling air having a temperature in a range from about 0 degrees to about room temperature to the object to be processed; and
applying a pressure on the adhesive.

11. The manufacturing method of the display device of claim 10, wherein the adhesive includes a pressure-sensitive adhesive.

12. The manufacturing method of the display device of claim 11, wherein the temperature of the cooling air is a temperature which increases a modulus of the adhesive.

13. The manufacturing method of the display device of claim 12, wherein the temperature of the cooling air is equal to or more than about 5 degrees, and equal to or less than about 18 degrees.

14. The manufacturing method of the display device of claim 12, wherein the cooling air is formed by a supply of compressed air supplied from an outside and passing through a vortex tube.

15. The manufacturing method of the display device of claim 14, wherein the compressed air includes clean-dry-air.

16. The manufacturing method of the display device of claim 10, further comprising:
detecting a temperature of the stage before applying the pressure on the adhesive.

17. The manufacturing method of the display device of claim 11, further comprising:
chucking a portion of the first surface of the electronic component; and
positioning a second portion of the second surface above a first portion of the second surface of the electronic component by bending the portion of the first surface of the electronic component.

18. The manufacturing method of the display device of claim 17, wherein the electronic component on which the adhesive is disposed includes a display panel and a circuit board.

19. The manufacturing method of the display device of claim 18, wherein applying the pressure on the adhesive includes:
applying the pressure on the first portion of the second surface and the second portion of the second surface, where a portion of the circuit board overlaps with the display panel.

20. The manufacturing method of the display device of claim 18, further comprising:
applying a pressure on a third portion of the second surface of the display panel spaced apart from the circuit board.
